(19) United States
(12) Patent Application Publication
(10) Pub. No.: US 2024/0292629 A1
(43) Pub. Date: Aug. 29, 2024

(54) THREE-DIMENSIONAL MEMORY DEVICES

(71) Applicant: Yangtze Memory Technologies Co., Ltd., Wuhan (CN)

(72) Inventors: Dongxue Zhao, Wuhan (CN); Tao Yang, Wuhan (CN); Wenxi Zhou, Wuhan (CN); Yuancheng Yang, Wuhan (CN); Zhiliang Xia, Wuhan (CN); Zongliang Huo, Wuhan (CN)

(21) Appl. No.: 18/296,182

(22) Filed: Apr. 5, 2023

Related U.S. Application Data
(63) Continuation of application No. PCT/CN2023/078608, filed on Feb. 28, 2023.

(51) Int. Cl. H10B 53/20; H01L 23/00; H01L 25/065; H01L 25/18; H10B 53/30; H10B 80/00

(52) U.S. Cl. CPC H10B 53/20; H01L 24/08; H01L 25/0657; H01L 25/18; H10B 53/30; H10B 80/00; H01L 2224/08145; H01L 2924/1431; H01L 2924/1441

(57) ABSTRACT

Embodiments of 3D memory devices and methods for forming the 3D memory device are disclosed. In one example, a 3D memory device includes a memory array and a peripheral circuit bonded to the memory array. The memory array includes a first multi-layer stacked structure, first capacitor structures penetrating the first multi-layer stacked structure, and a blocking structure penetrating the first multi-layer stacked structure. The first multi-layer stacked structure includes alternately stacked dielectric layers and conductive layers. Each of the first capacitor structures includes a dielectric layer and an electrode layer, where the dielectric layer of a first capacitor structure is disposed between the electrode layer of the first capacitor structure and the dielectric layers or the conductive layers of the first multi-layer stacked structure. The blocking structure separates one subset of the first capacitor structures from another subset of the first capacitor structures.

### CROSS-REFERENCE TO RELATED APPLICATIONS

This application is a continuation of International Application No. PCT/CN2023/078608, filed on Feb. 28, 2023, the disclosure of which is hereby incorporated by reference in its entirety.

### TECHNICAL FIELD

The present disclosure relates to three-dimensional (3D) memory devices and fabrication methods thereof.

### BACKGROUND

Planar memory cells are scaled to smaller sizes by improving process technology. circuit design, programming algorithm, and fabrication process. However, as feature sizes of the memory cells approach a lower limit, planar process and fabrication techniques become challenging and costly. As a result, memory density for planar memory cells approaches an upper limit. A 3D memory architecture can address the density limitation in planar memory cells. The 3D memory architecture includes a memory array and peripheral circuits for controlling signals to and from the memory array.

### SUMMARY

The present disclosure describes embodiments of 3D memory devices and methods for forming the 3D memory devices, as well as systems that include a 3D memory device.

For example, the present disclosure describes a method for forming a 3D memory device. The method includes forming a first multi-layer stacked structure over a substrate, where the first multi-layer stacked structure includes alternately stacked first layers and second layers, in which the second layers include a dielectric material. The method further includes forming, using a same mask, first holes and one or more slits penetrating the first multi-layer stacked structure, where each of the one or more slits separates subsets of the first holes from one another. The method further includes filling the first holes to form first capacitor structures, where each of the first capacitor structures comprises a dielectric layer and an electrode layer. The dielectric layer of a first capacitor structure is disposed between the electrode layer of the first capacitor structure and the first layers or the second layers of the first multi-layer stacked structure. The one or more slits are filled to form one or more blocking structures, where each of the one or more blocking structures comprises a dielectric layer and a conductive layer.

The present disclosure also describes a method for forming a 3D memory device. The method includes forming a first multi-layer stacked structure over a substrate, where the first multi-layer stacked structure comprises alternately stacked first layers and second layers. The second layers include a dielectric material. The method further includes forming first capacitor structures penetrating the first multi-layer stacked structure and blocking structures penetrating the first multi-layer stacked structure, where each of the blocking structures separates subsets of the first capacitor structures from one another. A second multi-layer stacked structure is formed over the first multi-layer stacked structure, where the second multi-layer stacked structure includes a first insulating layer, a word line layer over the first insulating layer, and a second insulating layer over the word line layer. The method further includes forming contacts penetrating the second multi-layer stacked structure, where the contacts are disposed over the blocking structures, and the contacts are in contact with the word line layer of the second multi-layer stacked structure.

The present disclosure also describes a 3D memory device. The 3D memory device includes a memory array, and the memory array includes a first multi-layer stacked structure, where the first multi-layer stacked structure includes alternately stacked dielectric layers and conductive layers. The 3D memory device further includes first capacitor structures penetrating the first multi-layer stacked structure, where each of the first capacitor structures includes a dielectric layer and an electrode layer. The dielectric layer of a first capacitor structure is disposed between the electrode layer of the first capacitor structure and the dielectric layers or the conductive layers of the first multi-layer stacked structure. The 3D memory device further includes a blocking structure penetrating the first multi-layer stacked structure, where the blocking structure separates one subset of the first capacitor structures from another subset of the first capacitor structures, and the blocking structure includes a dielectric layer and a conductive layer.

The present disclosure also describes a 3D memory device. The 3D memory device includes a memory array, and the memory array includes a first multi-layer stacked structure, where the first multi-layer stacked structure includes alternately stacked dielectric layers and conductive layers. The 3D memory device further includes first capacitor structures penetrating the first multi-layer stacked structure, and a blocking structure penetrating the first multi-layer stacked structure, where the blocking structure separates one subset of the first capacitor structures from another subset of the first capacitor structures. The 3D memory device further includes a second multi-layer stacked structure over the first multi-layer stacked structure, where the second multi-layer stacked structure includes a first insulating layer, a word line layer over the first insulating layer, and a second insulating layer over the word line layer. The 3D memory device further includes a contact penetrating the second multi-layer stacked structure, where the contact is disposed over the blocking structure, and the contact is in contact with the word line layer of the second multi-layer stacked structure.

Other aspects, features and various advantages present in some implementations will be readily apparent from the following detailed description, the accompanying drawings, and the claims.

### BRIEF DESCRIPTION OF THE DRAWINGS

The accompanying drawings, which are incorporated herein and form a part of the specification, illustrate embodiments of the present disclosure and, together with the description, further serve to explain the present disclosure and to enable a person of ordinary skill in the pertinent art to make and use the present disclosure.

FIG. 1A illustrates a schematic view of an example 3D memory device, according to some embodiments.

FIG. 1B illustrates a side view of a cross-section of the 3D memory device, according to some embodiments.

FIG. 2 illustrates a side view of a cross-section of an example 3D memory device, according to some embodiments of the present disclosure.

FIGS. 3-12 illustrate a fabrication process for forming the 3D memory device, according to some embodiments of the present disclosure.

FIG. 13 illustrates a flowchart of an example method for forming a 3D memory device, according to some embodiments of the present disclosure.

### DETAILED DESCRIPTION

Although specific configurations and arrangements are discussed, it should be understood that this is done for illustrative purposes only. A person of ordinary skill in the pertinent art will recognize that other configurations and arrangements can be used without departing from the spirit and scope of the present disclosure. It will be apparent to a person of ordinary skill in the pertinent art that the present disclosure can also be employed in a variety of other applications.

References in the specification to “one embodiment,” “an embodiment,” “an example embodiment,” “some embodiments,” etc., indicate that the embodiment described may include a particular feature, structure, or characteristic, but other embodiments may not necessarily include the particular feature, structure, or characteristic. Moreover, such phrases do not necessarily refer to the same embodiment. Further, when a particular feature, structure, or characteristic is described in connection with an embodiment, it would be within the knowledge of a person of ordinary skill in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only conveys the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductor and contact layers (in which interconnect lines and/or vertical interconnect access (via) contacts are formed) and one or more dielectric layers.

As used herein, the term “about” indicates the value of a given quantity that can vary based on a particular technology node associated with the subject semiconductor device. Based on the particular technology node, the term “about” can indicate a value of a given quantity that varies within the value.

As used herein, the term “3D memory device” refers to a semiconductor device with vertically oriented strings of memory cell transistors (referred to herein as “memory strings,” such as NAND memory strings) on a laterally oriented substrate so that the memory strings extend in the vertical direction with respect to the substrate. As used herein, the term “vertical/vertically” means nominally perpendicular to the lateral surface of the substrate.

As the feature size of the semiconductor manufacturing process becomes smaller, the storage density of the storage device becomes higher, and the size reduction of traditional memory (e.g., 1T1C DRAM) is close to its manufacturing limit. With the increasing storage density requirements, the manufacturing process of capacitors in DRAM is more complicated under miniature scales, such that the electric leakage becomes more significant, the retention time is reduced, the static power consumption is increased, and the operating voltage margin is degraded. Therefore, there is a need for a memory device to maintain a high storage density but without the above-noted deficiencies. Ferroelectric memory (FeRAM) stores data based on ferroelectric polarization and can increase the capacity of the storage capacitor through polarized charge. However, most ferroelectric memories still maintain a two-dimensional (2D) structure to make them a sub-optimal option to replace DRAM. 2D ferroelectric memory can learn from the 3D NAND architecture to achieve high-density storage, for example, by realizing a multi-capacitor stacked structure.

In the present disclosure, a 3D memory device is provided. The 3D memory device includes capacitor structures and blocking structures penetrating a multi-layer stacked structure, where the blocking structures separate subsets of the capacitor structure from one another. The capacitor structures and the blocking structures may be formed by etching the multi-layer stacked structure using a same mask to form holes and slits and then filling the holes and slits with multiple layers of dielectric materials and conductive materials. In this way, the holes and slits can be formed within substantially a same time period, and the holes and the slits can be filled to form the capacitor structures and blocking structures within substantially a same time period. As a result, the complexity and cost of the fabrication process can be reduced, and the product yield can be increased in some cases. Furthermore, the 3D memory device includes contacts disposed over the blocking structures, which can, in some cases, reduce the resistance and thus increase the storage capacity of the device.

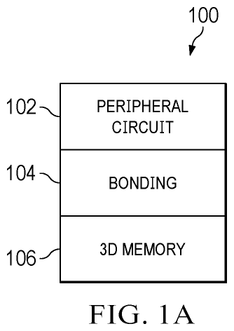

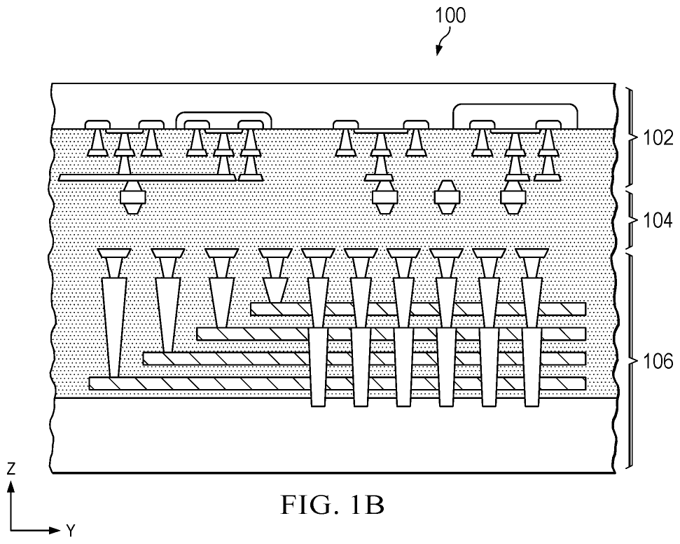

FIG. 1A illustrates a schematic view of an example 3D memory device 100, according to some embodiments. 3D memory device 100 represents an example of a non-monolithic 3D memory device. The term “non-monolithic” means that the components of 3D memory device 100 (e.g., peripheral circuit and memory array) can be formed separately on different substrates and then joined to form a 3D memory device.

3D memory device 100 can include a first semiconductor structure 102 including peripheral circuits. The peripheral circuits can be implemented, for example, with advanced logic processes (e.g., technology nodes of 90 nm, 80 nm, 65 nm, 55 nm, 45 nm, 40 nm, 32 nm, 28 nm, 22 nm, 20 nm, 16 nm, 14 nm, 10 nm, 7 nm, 5 nm, 3 nm, etc.) to achieve high speed. In some embodiments, the peripheral circuits in first semiconductor structure 102 are implemented using complementary metal-oxide-semiconductor (CMOS) technology.

In some embodiments, the peripheral circuits include any suitable digital, analog, and/or mixed-signal peripheral circuits used for facilitating the operation of 3D memory device 100. For example, the peripheral circuits can include one or more of a page buffer, a decoder (e.g., a row decoder and a column decoder), a sense amplifier, a driver, a charge pump, a current or voltage reference, or any active or passive components of the circuits (e.g., transistors, diodes, resistors, or capacitors).

3D memory device 100 can also include a second semiconductor structure 106 including an array of 3D memory array. In some embodiments, the second semiconductor structure 106 can be a memory device such as dynamic random-access memory (DRAM) or static RAM (SRAM). Each DRAM cell can include a capacitor for storing a bit of data as a positive or negative electrical charge as well as one or more transistors that control access to it. In one example, each DRAM cell is a one-transistor, one-capacitor (1T1C) cell.

3D memory device 100 can further include an interconnection structure 104 between first and second semiconductor structures 102 and 106. First and second semiconductor structures 102 and 106 can be fabricated separately (and in parallel in some embodiments) such that the thermal budget of fabricating one of first and second semiconductor structures 102 and 106 does not limit the processes of fabricating another one of first and second semiconductor structures 102 and 106. Moreover, a large number of interconnects (e.g., bonding contacts via hybrid bonding) can be formed through the interconnection structure to make direct, short, electrical connections between first semiconductor structure 102 and second semiconductor structure 106, as opposed to the long-distance chip-to-chip data bus on the circuit board, thereby eliminating chip interface delay and achieving high-speed I/O throughput with reduced power consumption. Data transfer between the array of 3D memory strings in second semiconductor structure 106 and the peripheral circuits in first semiconductor structure 102 can be performed through the interconnects (e.g., bonding contacts via hybrid bonding) across the interconnection structure 104. Furthermore, by vertically integrating first and second semiconductor structures 102 and 106, the chip size can be reduced, and the memory cell density can be increased.

The relative positions of stacked first and second semiconductor structures 102 and 106 and the interconnection structure 104 are not limited. In some embodiments, second semiconductor structure 106 can be disposed above first semiconductor structure 102. Nevertheless, in such implementations, interconnection structure 104 can be also formed vertically between first and second semiconductor structures 102 and 106.

FIG. 1B illustrates a side view of a cross-section of the exemplary 3D memory device 100, according to some embodiments of the present disclosure. In some embodiments, 3D memory device 100 is a bonded chip including first structure 102 and second structure 106 stacked below first structure 102. First and second structures 102 and 106 are jointed at interconnection structure 104, according to some embodiments. As used herein, whether one component (e.g., a layer or a device) is “on,” “above,” “over” or “below” another component (e.g., a layer or a device) of a device (e.g., 3D memory device 100) is determined relative to the structure or layer (e.g., second structure 106) in the z-direction (i.e., the vertical direction) when the structure or layer (e.g., second structure 106) is positioned in the lowest tier of the device in the z-direction. The same notion for describing spatial relationships is applied throughout the present disclosure.

In some embodiments, first structure 102 can include peripheral circuits, and the peripheral circuits can be configured to control signals to and from the memory array of 3D memory device 100. The peripheral circuits can be any suitable digital, analog, and/or mixed-signal control and sensing circuits used for facilitating the operation of 3D memory device 100 including, but not limited to, a page buffer, a decoder (e.g., a row decoder and a column decoder), a sense amplifier, a driver (e.g., a word line driver), a charge pump, a current or voltage reference, or any active or passive components of the circuit (e.g., transistors, diodes, resistors, or capacitors). The peripheral circuits can include transistors formed “on” a substrate (not shown), in which the entirety or part of the transistors are formed in the substrate and/or directly on the substrate. Isolation regions (e.g., shallow trench isolations (STIs)) and doped regions (e.g., source regions and drain regions of the transistors) can be formed in the substrate as well. The transistors are high-speed with advanced logic processes, according to some embodiments. In some embodiments, the peripheral circuit(s) may further include other circuits compatible with the advanced logic processes including logic circuits, such as processors and programmable logic devices (PLDs), or memory circuits, such as SRAM and DRAM.

In some embodiments, first structure 102 further includes an interconnect layer to transfer electrical signals to and from the peripheral circuits. The interconnect layer can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “inter-metal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include one or more dielectric materials including, but not limited to, silicon oxide, silicon nitride, silicon oxynitride, low dielectric constant (low-k) dielectrics, or any combination thereof.

First structure 102 can further include a bonding layer. The bonding layer can include bonding contacts and dielectrics electrically isolating the bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts and surrounding dielectrics in the bonding layer can be used for hybrid bonding.

Second structure 106 can also include a bonding layer that includes a plurality of bonding contacts and dielectrics electrically isolating bonding contacts. The bonding contacts of second structure 106 can include conductive materials including, but not limited to, W, Co, Cu, Al, silicides, or any combination thereof. The remaining area of the bonding layer of the second structure 106 can be formed with dielectrics including, but not limited to, silicon oxide, silicon nitride, silicon oxynitride, low-k dielectrics, or any combination thereof. The bonding contacts and surrounding dielectrics in the bonding layer of second structure 106 can be used for hybrid bonding.

First structure 102 can be bonded on top of second structure 106 in a face-to-face manner. In some embodiments, first and second structures 102 and 106 can be bonded by hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some embodiments, second structure 106 further includes an interconnect layer to transfer electrical signals. The interconnect layer can include a plurality of interconnects, such as MEOL interconnects and BEOL interconnects. The interconnect layer can further include one or more ILD layers in which the interconnect lines and VIA contacts can form. The interconnect lines and VIA contacts in the interconnect layer can include conductive materials including, but not limited to W, Co, Cu, Al, silicides, or any combination thereof. The ILD layers in the interconnect layer can include one or more materials including, but not limited to, silicon oxide, silicon nitride, silicon oxynitride, low-k dielectrics, or any combination thereof.

3D memory device 100 can further include interconnection structure 104 between first and second semiconductor structures 102 and 106. A large number of interconnects (e.g., bonding contacts via hybrid bonding) can be formed through the interconnection structure to make direct, short, electrical connections between first semiconductor structure 102 and second semiconductor structure 106, as opposed to the long-distance chip-to-chip data bus on the circuit board, thereby eliminating chip interface delay and achieving high-speed I/O throughput with reduced power consumption. Data transfer between the array of 3D memory strings in second semiconductor structure 106 and the peripheral circuits in first semiconductor structure 102 can be performed through the interconnects (e.g., bonding contacts via hybrid bonding) across the interconnection structure. Furthermore, by vertically integrating first and second semiconductor structures 102 and 106, the chip size can be reduced, and the memory cell density can be increased. In some embodiments, interconnection structure 104 can include the bonding layers of first semiconductor structure 102 and second semiconductor structure 106.

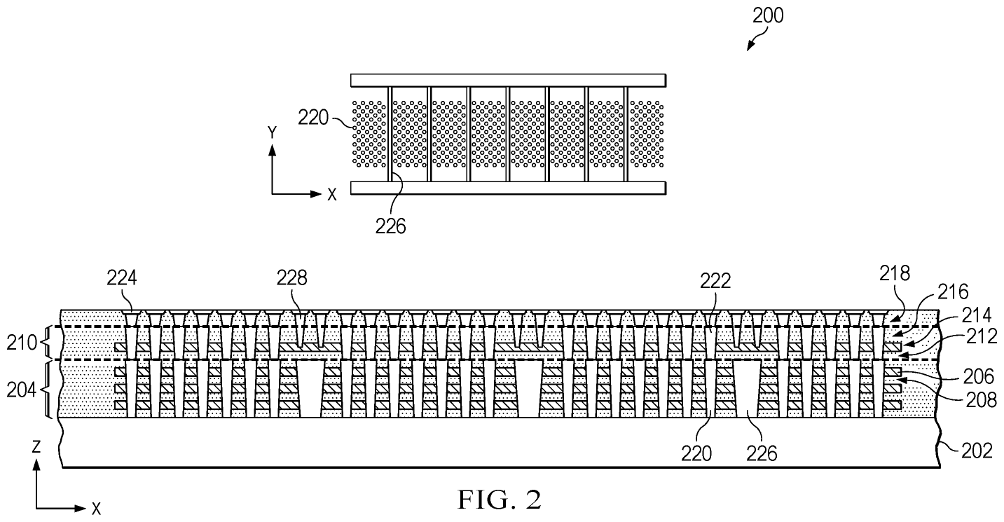

In some embodiments, 3D memory device is a memory device in which memory cells are provided in the form of an array of memory strings. FIG. 2 illustrates a side view of a cross-section of an example 3D memory device 200, according to some embodiments of the present disclosure. With reference to FIG. 1B and FIG. 2, the staircase structure of the 3D memory device can be formed along the Y direction. As shown in FIG. 2, 3D memory device 200 can include a first multi-layer stacked structure 204 disposed over substrate 202. In some embodiments, substrate 202 includes silicon (e.g., single crystalline silicon, c-Si), silicon germanium (SiGe), gallium arsenide (GaAs), germanium (Ge), silicon-on-insulator (SOI), or any other suitable materials. First multi-layer stacked structure 204 includes alternately stacked dielectric layers 208 and conductive layers 206. The number of the pairs of conductive layers 206 and dielectric layers 208 determines the number of memory cells in 3D memory device 200. As shown, conductive layers 206 and dielectric layers 208 can alternate in the vertical direction. In other words, except the ones at the top or bottom of first multi-layer stacked structure 204, each conductive layer 206 can be sandwiched between two dielectric layers 208, and each dielectric layer 208 can be sandwiched between two conductive layers 206. Conductive layers 206 can include conductive materials, for example, including, but not limited to, W, Co, Cu, Al, polysilicon, doped silicon, silicides, or any combination thereof. Each conductive layer 206 can include, for example, a gate electrode (gate line) surrounded by an adhesive layer and a gate dielectric layer. The gate electrode of conductive layer 206 can extend laterally as a word line, ending at one or more staircase structures of multi-layer stacked structure 204. Dielectric layers 208 can include one or more dielectric materials, for example, including, but not limited to, silicon oxide, silicon nitride, silicon oxynitride, or any combination thereof.

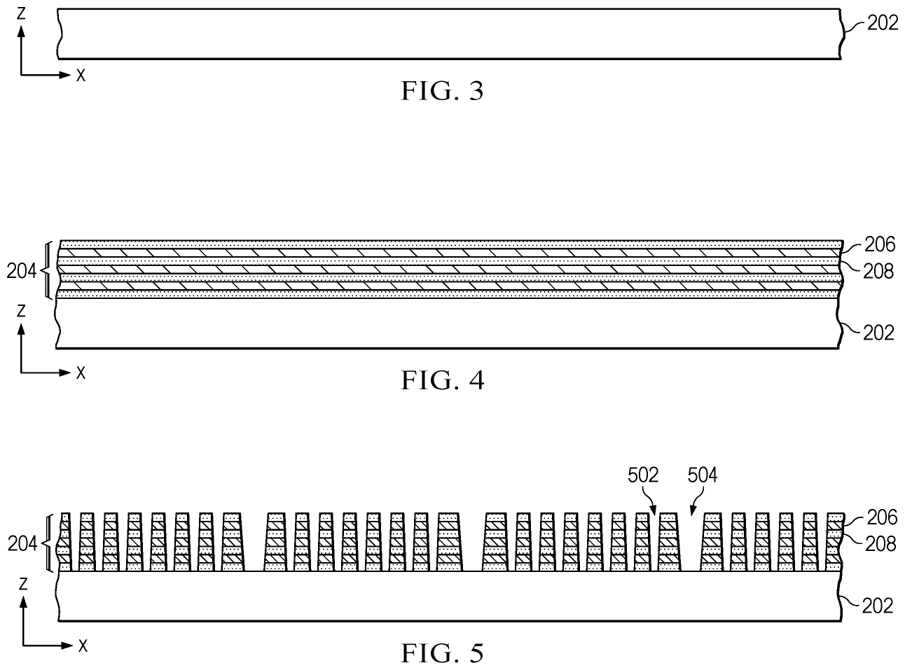

3D memory device 200 further includes first capacitor structures 220 penetrating the first multi-layer stacked structure 204. In some embodiments, each of the first capacitor structures 220 can include a dielectric layer and an electrode layer. The dielectric layers and electrode layers of the first capacitor structures 220 are described below in greater detail with reference to FIGS. 3-12.

3D memory device 200 further includes one or more blocking structures 226 penetrating first multi-layer stacked structure 204. Each of blocking structures 226 separates one subset of first capacitor structures 220 from another subset of first capacitor structures 220. In some embodiments, blocking structure 226 includes a dielectric layer and a conductive layer. The dielectric layers and conductive layers of blocking structures 226 are described below in greater detail with reference to FIGS. 3-12.

3D memory device 200 further includes second multi-layer stacked structure 210 over first multi-layer stacked structure 204. Second multi-layer stacked structure 210 includes a first insulating layer 212, a word line layer 214 over the first insulating layer 212, and a second insulating layer 216 over the word line layer 214. In some embodiments, first insulating layer 212 can be composed of one or more dielectric materials, for example, including, but not limited to, silicon oxide, silicon nitride, silicon oxynitride, or any combination thereof. Second insulating layer 216 can be composed of one or more dielectric materials, for example, including, but not limited to, silicon oxide, silicon nitride, silicon oxynitride, or any combination thereof. In some embodiments, first insulating layer 212 and second insulating layer 216 can include a same material as one another. In some embodiments, first insulating layer 212 and second insulating layer 216 can include a different material from one another. In some embodiments, word line layer 214 can include conductive materials, for example, including, but not limited to, W, Co, Cu, Al, polysilicon, doped silicon, silicides, or any combination thereof.

3D memory device 200 further includes second capacitor structures 222 penetrating second multi-layer stacked structure 210. Second capacitor structures 222 are disposed over first capacitor structures 220. In some embodiments, each of second capacitor structures 222 includes a dielectric layer and a conductive filling material. The dielectric layers and conductive filling material of second capacitor structures 222 are described below in greater detail with reference to FIGS. 3-12.

3D memory device 200 further includes bit lines 224 over second multi-layer stacked structure 210. In some embodiments, each of bit lines 224 is disposed over a respective one of second capacitor structures 222. Bit lines 224 are formed penetrating dielectric layer 218 disposed over second multi-layer stacked structure 210, according to some embodiments. In some embodiments, bit lines 224 can include bit line contacts formed by forming openings in dielectric layer 218, followed by filling the openings with conductive materials such as W, Co, Cu, Al, Ti, TiN, Ta, TaN, doped silicon, silicides, or any combination thereof, and deposited by CVD, PVD, sputtering, evaporating, plating, or any combination thereof. In some embodiments, bit lines 224 can be configured to read data stored in the memory cells of 3D memory device 200.

3D memory device 200 further includes one or more contacts 228 penetrating second multi-layer stacked structure 210. In some embodiments, contact 228 penetrates through dielectric layer 218 and second insulating layer 216 to word line layer 214 such that contact 228 is in contact with word line layer 214 of second multi-layer stacked structure 210. In some embodiments, contacts 228 are disposed over blocking structures 226, which can reduce the resistance and thus increase the storage capacity of memory device 200. In some embodiments, a respective contact 228 is disposed over a blocking structure 226. In some embodiments, more than one (e.g., two) contacts 228 are disposed over a blocking structure 226. In some embodiments, a respective contact 228 is not disposed over all blocking structures 226. For example, in some cases, at least one contact 228 is disposed at a first subset of blocking structures 226, while no contact 228 is disposed at a second subset of blocking structures 226. In some embodiments, the number of contacts 228 disposed over blocking structures 226 can be different. For example, in some cases, only one contact 228 is disposed over a first subset of blocking structures 226, while two or more contacts 228 are disposed over a second subset of blocking structures 226.

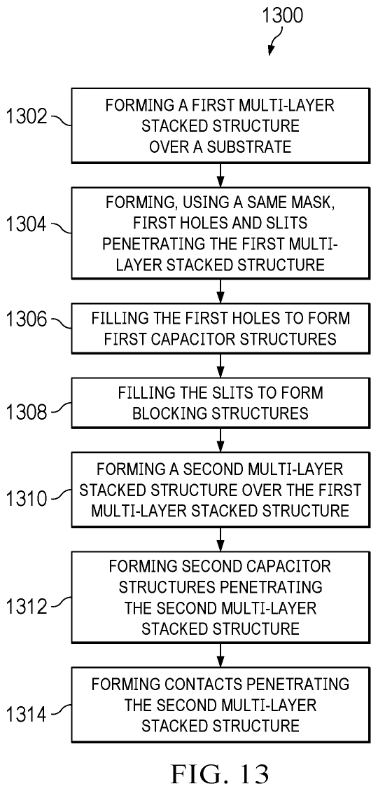

FIGS. 3-12 illustrate a fabrication process for forming example 3D memory devices, according to some embodiments of the present disclosure. FIG. 13 illustrates a flowchart of a method 1300 for forming an example 3D memory device, according to some embodiments of the present disclosure. Examples of the 3D memory device depicted in FIGS. 3-12 include 3D memory devices 100 and 200 depicted in FIGS. 1A, 1B, and 2. FIG. 13 will be described with reference to FIGS. 3-12 in greater detail below. The operations shown in method 1300 are not exhaustive and other operations can be performed as well, for example, before, after, or between any of the illustrated operations. Further, some of the operations may be performed simultaneously, or in a different order than shown in FIGS. 3-13.

Referring to FIG. 13, method 1300 starts at operation 1302, in which a first multi-layer stacked structure is formed over a substrate. As illustrated in FIG. 3, substrate 202 is provided. In some embodiments, substrate 202 includes silicon (e.g., single crystalline silicon, c-Si), silicon germanium (SiGe), gallium arsenide (GaAs), germanium (Ge), SOI, or any other suitable materials.

Then, referring to FIG. 4, first multi-layer stacked structure 204 is formed over substrate 202. As shown, first multi-layer stacked structure 204 includes alternately stacked first layers 206 and second layers 208. In some embodiments, both first layers 206 and second layers 208 can be dielectric layers. In some embodiments, first layers 206 can be conductive layers, and second layers 208 can be dielectric layers. In one example, during an early stage of a manufacturing process, first multi-layer stacked structure 204 may include alternately stacked first dielectric layers and second dielectric layers, and during a later stage conductive layers may be substituted for the first dielectric layers such that the first multi-layer stacked structure 204 includes alternately stacked conductive layers and dielectric layers. In yet another example, first multi-layer stacked structure 204 can be formed as including alternately stacked conductive layers and dielectric layers throughout a manufacturing process.

The number of the pairs of conductive layers 206 and dielectric layers 208 determines the number of memory cells in 3D memory device 200. Conductive layers 206 can include conductive materials, for example, including, but not limited to, W, Co, Cu, Al, polysilicon, doped silicon, silicides, or any combination thereof. Each conductive layer 206 can include, for example, a gate electrode (gate line) surrounded by an adhesive layer and a gate dielectric layer. The gate electrode of conductive layer 206 can extend laterally as a word line, ending at one or more staircase structures of first multi-layer stacked structure 204. Dielectric layers 208 can include one or more dielectric materials, for example, including, but not limited to, silicon oxide, silicon nitride, silicon oxynitride, or any combination thereof.

At operation 1304 of FIG. 13, first holes and slits penetrating the first multi-layer stacked structure are formed using a same mask. Referring to FIG. 5, first holes 502 and slits 504 are formed within first multi-layer stacked structure 204. In some embodiments, first holes 502 and slits 504 can be formed by etching first multi-layer stacked structure 204 using a same mask such that first holes 502 and slits 504 can be formed within substantially a same time period.

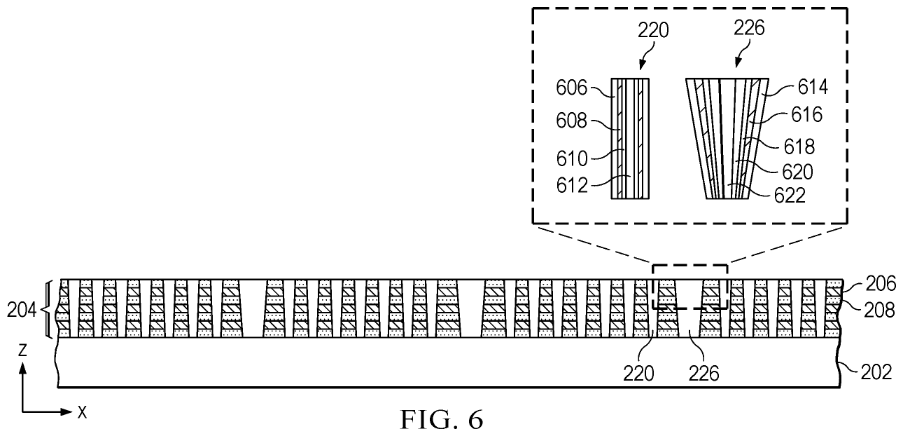

At operation 1306 of FIG. 13, the first holes are filled to form first capacitor structures. Referring to FIG. 6, first holes 502 are filled to form first capacitor structures 220. In some embodiments, each of first capacitor structures 220 includes a dielectric layer 608 and an electrode layer 610. In some embodiments, dielectric layer 608 includes a ferroelectric material or an anti-ferroelectric material. In some embodiments, dielectric layer 608 includes one or more dielectric materials, for example, including, but not limited to, hafnium zirconium oxide (HfZrO), silicon:hafnium-oxide (Si:HfO), aluminum:hafnium-oxide (Al:HfO), zirconium oxide (ZrO), or any combination thereof. In some embodiments, electrode layer 610 includes conductive materials, for example, including, but not limited to, polysilicon, titanium nitride (TiN), tungsten (W), platinum (Pt), ruthenium (Ru), tantalum nitride (TaN), or any combination thereof.

In some embodiments, dielectric layer 608 is disposed between electrode layer 610 and alternately stacked layers of the first multi-layer stacked structure 204. In the shown example, dielectric layer 608 is disposed between electrode layer 610 and a portion 606 of conductive layer 206 of first multi-layer stacked structure 204.

First capacitor structures 220 can further include a conductive filler material 612. In some embodiments, conductive filler material 612 includes, but is not limited to, polysilicon, TiN, W. Pt, Ru, TaN, or any combination thereof.

In some embodiments, conductive filler material 612 and electrode layer 610 can be composed of the same material(s). In some embodiments, conductive filler material 612 and electrode layer 610 can be composed of different materials.

In some embodiments, first capacitor structure 220 can have a cylinder shape (e.g., a pillar shape). As shown, conductive filler material 612, electrode layer 610, and dielectric layer 608 are arranged radially from the center of first capacitor structure 220 toward the outer surface of the pillar in this order, according to some embodiments.

At operation 1308 of FIG. 13, the slits are filled to form blocking structures. Still referring to FIG. 6, slits 504 are filled to form blocking structures 226. In some embodiments, each of blocking structures 226 comprises dielectric layer 616 and conductive layer 618. In some embodiments, dielectric layer 616 includes a ferroelectric material or an anti-ferroelectric material. In some embodiments, dielectric layer 616 includes one or more dielectric materials, for example, including, but not limited to, HfZrO, Si:HfO, Al:HfO, ZrO, or any combination thereof. In some embodiments, conductive layer 618 includes conductive materials, for example, including, but not limited to, polysilicon, TiN, W, Pt, Ru, TaN, or any combination thereof.

In some embodiments, dielectric layer 616 is disposed between conductive layer 618 and alternately stacked layers of the first multi-layer stacked structure 204. In the shown example, dielectric layer 616 is disposed between conductive layer 618 and a portion 614 of conductive layer 206 of first multi-layer stacked structure 204.

In some embodiments, each of blocking structures 226 further includes conductive layer 620. In some embodiments, conductive layer 620 includes conductive materials, for example, including, but not limited to, polysilicon, TiN, W, Pt, Ru. TaN, or any combination thereof. In some embodiments, conductive layer 618 and conductive layer 620 are composed of the same conductive material(s). In some embodiments, conductive layer 618 and conductive layer 620 are composed of different conductive materials.

In some embodiments, each of blocking structures 226 further includes a dielectric filling material 622. In some embodiments, dielectric filling material 622 can include, but is not limited to, silicon oxide, silicon nitride, or any combination thereof.

In some embodiments, dielectric layers 608 of the first capacitor structures 220 and dielectric layers 616 of blocking structures 226 are composed of a same dielectric material. In some embodiments, electrode layers of the first capacitor structures 220 and the conductive layer 618 of the blocking structures 226 are composed of a same conductive material.

In some embodiments, blocking structures 226 can have a cylinder shape (e.g., a pillar shape) or a quasi-cylinder shape (i.e., inconsistent critical dimension along the structure). As shown, dielectric filling material 622, conductive layer 620, conductive layer 618, and dielectric layer 616 are arranged radially from the center of blocking structures 226 toward the outer surface of the pillar in this order, according to some embodiments.

In some embodiments, first holes 502 and slits 504 are filled within substantially a same time period to form first capacitor structures 220 and blocking structures 226.

As noted above, first capacitor structures 220 and blocking structures 226 may be formed by etching multi-layer stacked structure 204 using a same mask to form holes 502 and slits 504 and then filling holes 502 and slits 504 with multiple layers of dielectric materials and conductive materials. In this way, holes 502 and slits 504 are formed within substantially a same time period, and holes 502 and slits 504 are filled to form the first capacitor structures 220 and blocking structures 226 within substantially a same time period. As a result, the complexity and cost of the fabrication process can be reduced, and the product yield can be increased in some cases

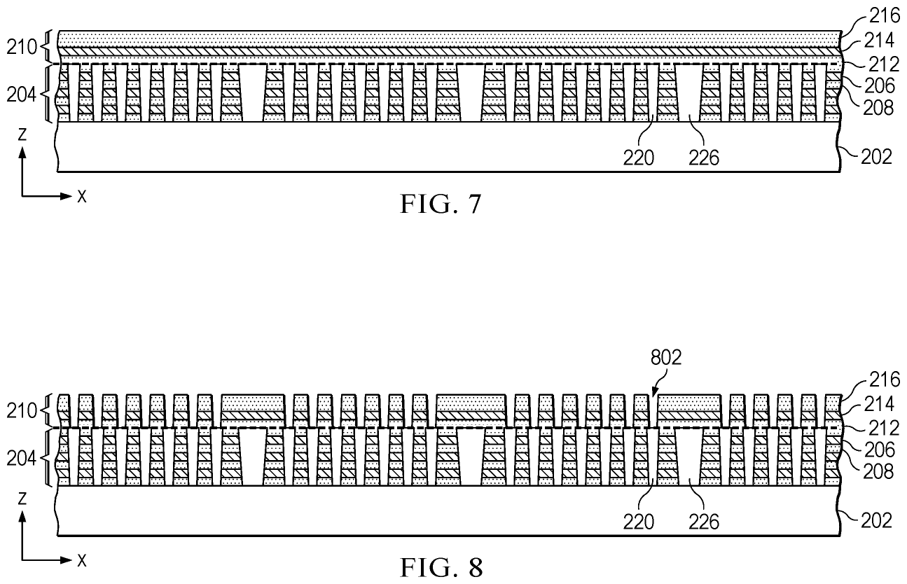

At operation 1310 of FIG. 13, a second multi-layer stacked structure is formed over the first multi-layer stacked structure. Referring to FIG. 7, second multi-layer stacked structure 210 is formed over first multi-layer stacked structure 204. In some embodiments, second multi-layer stacked structure 210 includes first insulating layer 212, word line layer 214, and second insulating layer 216. In some embodiments, forming second multi-layer stacked structure 210 includes forming first insulating layer 212 over first multi-layer stacked structure 204, forming word line layer 214 over first insulating layer 212, and forming second insulating layer 216 over word line layer 214. In some embodiments, first insulating layer 212 is composed of one or more dielectric materials including, but not limited to, silicon oxide, silicon nitride, or any combination thereof. In some embodiments, second insulating layer 216 is composed of one or more dielectric materials including, but not limited to, silicon oxide, silicon nitride, or any combination thereof. In some embodiments, first insulating layer 212 and second insulating layer 216 are composed of the same dielectric material(s). In some embodiments, first insulating layer 212 and second insulating layer 216 are composed of different dielectric materials from one another. In some embodiments, word line layer 214 is composed of conductive materials including, but not limited to, polysilicon, TiN, W. Pt, Ru, TaN, or any combination thereof.

At operation 1312 of FIG. 13, second capacitor structures are formed penetrating the second multi-layer stacked structure. Referring to FIG. 8, second holes 802 are formed penetrating second multi-layer stacked structure 210. In some embodiments, second holes 802 can be formed by etching second multi-layer stacked structure 210. In some embodiments, second holes 802 are formed over first capacitor structures 220. In some embodiments, a respective second hole 802 is disposed over a first capacitor structure 220. In some embodiments, second holes 802 may be disposed over only a subset of first capacitor structures 220. For example, second holes 802 may be disposed over a first subset of first capacitor structures 220, while no second holes 802 are disposed over a second subset of first capacitor structures 220.

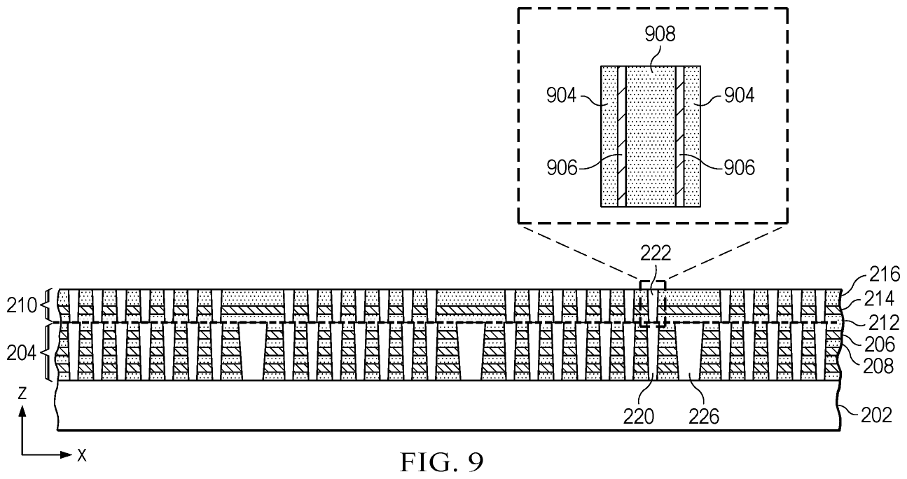

Referring to FIG. 9, second holes 802 are filled to form second capacitor structures 222. In some embodiments, each of second capacitor structures 222 includes a dielectric layer 906 and a conductive filling material 908. In some embodiments, dielectric layer 906 of second capacitor structure 222 is disposed between conductive filling material 908 and the stacked layers of second multi-layer stacked structure 210. In the shown example, dielectric layer 906 is disposed between conductive filling material 908 and a portion 904 of word line layer 214 of second multi-layer stacked structure 210. In some embodiments, dielectric layer 906 is composed of one or more dielectric materials, for example, including, but not limited to, HfZrO, Si:HfO, Al:HfO, ZrO, or any combination thereof. In some embodiments, conductive filling material 908 includes, but is not limited to, polysilicon, TiN, W, Pt, Ru, TaN, or any combination thereof.

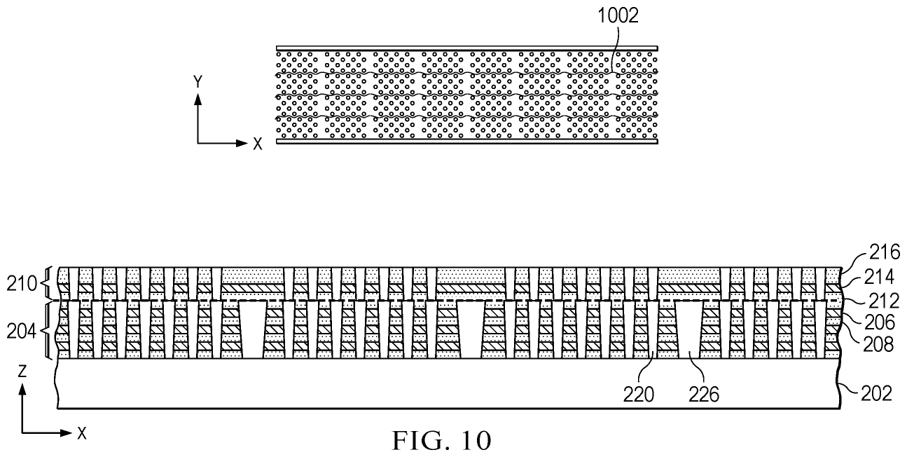

In some embodiments, word line blocking structures are formed within the second multi-layer stacked structure. Referring to FIG. 10, word line blocking structures 1002 are formed penetrating second multi-layer stacked structure 210. In some embodiments, each of word line blocking structures 1002 penetrates through at least second insulating layer 216 and the word line layer 214 of the second multi-layer stacked structure 210. An extending direction of the word line blocking structures 1002 can be perpendicular to an extending direction of the blocking structures 226. In some embodiments, word line blocking structures 1002 can be formed by etching second multi-layer stacked structure 210 to form word line slits and then filling the word line slits with a dielectric material.

In some embodiments, as shown in FIG. 10, word line blocking structures 1002 and second capacitor structures 222 are arranged in a staggered manner such that word line blocking structures 1002 form a wavy outline.

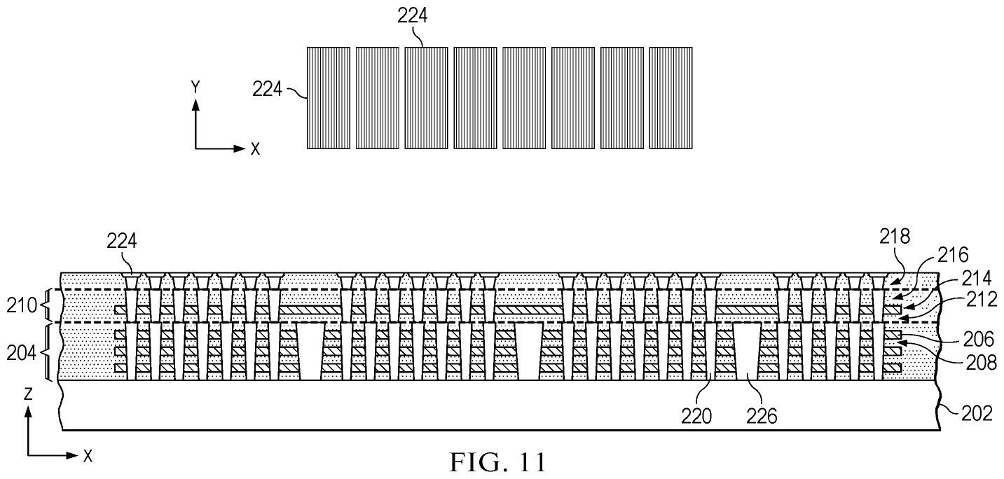

In some embodiments, referring to FIG. 11, bit lines 224 are formed over second multi-layer stacked structure 210. In some embodiments, bit lines 224 are formed by forming dielectric layer 218 over second multi-layer stacked structure 210 and forming bit lines 224 penetrating dielectric layer 218. In some embodiments, dielectric layer 218 includes one or more dielectric materials, for example, including, but not limited to, silicon oxide, silicon nitride, silicon oxynitride, or any combination thereof. In some embodiments, each of bit lines 224 is disposed over a respective one of second capacitor structures 222.

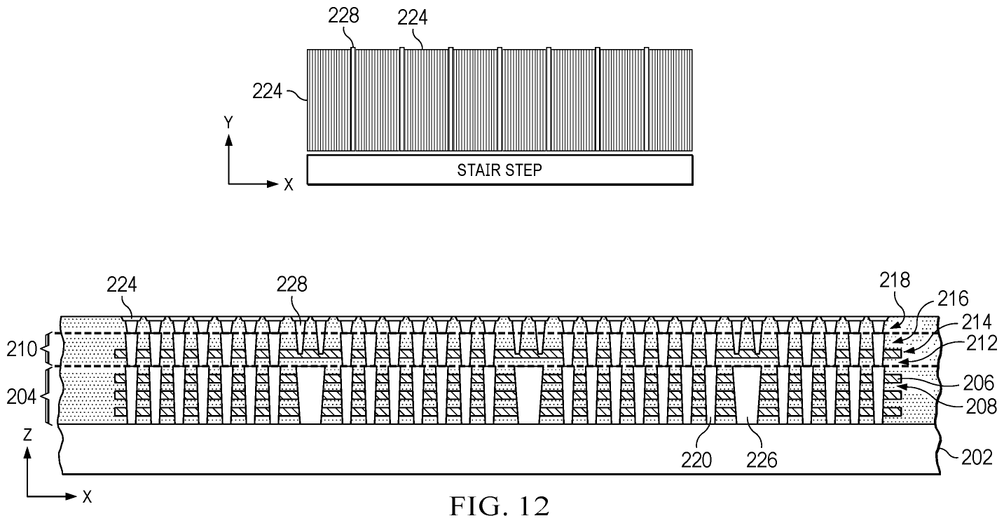

At operation 1314 of FIG. 13, contacts are formed penetrating the second multi-layer stacked structure. Referring to FIG. 12, contacts 228 are formed penetrating second multi-layer stacked structure 210. In some embodiments, a contact 228 penetrates through dielectric layer 218 and second insulating layer 216 to word line layer 214 such that contact 228 is in contact with word line layer 214 of second multi-layer stacked structure 210. In some embodiments, contacts 228 are composed of conductive materials including, but not limited to, W, Co, Cu, or Al, or any combination thereof.

In some embodiments, contacts 228 are disposed over blocking structures 226, which can reduce the resistance and thus increase the storage capacity of the device. In some embodiments, a respective contact 228 is disposed over a blocking structure 226. In some embodiments, more than one (e.g., two) contacts 228 are disposed over a blocking structure 226. In some embodiments, a respective contact 228 is not disposed over all blocking structures 226. In one example, at least one contact 228 is disposed at a first subset of blocking structures 226, while no contact 228 is disposed at a second subset of blocking structures 226. In some embodiments, the number of contacts 228 disposed over different blocking structures 226 can be different. In one example, only one contact 228 can be disposed over a first subset of blocking structures 226, while two or more contacts 228 can be disposed over a second subset of blocking structures 226.

According to one aspect of the present disclosure, a method for forming a three-dimensional (3D) memory device includes: forming a first multi-layer stacked structure over a substrate, wherein the first multi-layer stacked structure includes alternately stacked first layers and second layers, in which the second layers include a dielectric material; forming, using a same mask, first holes and one or more slits penetrating the first multi-layer stacked structure, wherein each of the one or more slits separates subsets of the first holes from one another; filling the first holes to form first capacitor structures, wherein each of the first capacitor structures comprises a dielectric layer and an electrode layer, wherein the dielectric layer of a first capacitor structure is disposed between the electrode layer of the first capacitor structure and the first layers or the second layers of the first multi-layer stacked structure; and filling the one or more slits to form one or more blocking structures, wherein each of the one or more blocking structures comprises a dielectric layer and a conductive layer.

In some embodiments, the dielectric layer of each of the first capacitor structures comprises a ferroelectric material or an anti-ferroelectric material; and the dielectric layer of each of the one or more blocking structures comprises a ferroelectric material or an anti-ferroelectric material.

In some embodiments, each of the one or more blocking structures further comprises a dielectric filling material.

In some embodiments, the method further includes forming a second multi-layer stacked structure over the first multi-layer stacked structure. Forming the second multi-layer stacked structure comprises: forming a first insulating layer over the first multi-layer stacked structure; forming a word line layer over the first insulating layer; and forming a second insulating layer over the word line layer.

In some embodiments, the method further includes: forming second holes penetrating the second multi-layer stacked structure, wherein the second holes are disposed over the first capacitor structures; and filling the second holes to form second capacitor structures, wherein each of the second capacitor structures comprises a dielectric layer and a conductive filling material.

In some embodiments, the method further includes: forming word line slits penetrating the second multi-layer stacked structure, wherein each of the word line slits penetrates through at least the second insulating layer of the second multi-layer stacked structure and the word line layer of the second multi-layer stacked structure, and wherein an extending direction of the word line slits is perpendicular to an extending direction of the one or more blocking structures.

In some embodiments, the method further includes: forming bit lines over the second multi-layer stacked structure, wherein each of the bit lines is disposed over at least a respective one of the second capacitor structures.

In some embodiments, the method further includes: forming contacts penetrating the second multi-layer stacked structure, wherein the contacts are disposed over the blocking structures, wherein the contacts penetrate through the second insulating layer of the second multi-layer stacked structure to the word line layer of the second multi-layer stacked structure, and wherein the contacts are in contact with the word line layer of the second multi-layer stacked structure.

In some embodiments, filling the first holes to form the first capacitor structures and filling the one or more slits to form the one or more blocking structures comprises: simultaneously filling the first holes to form the first capacitor structures and filling the one or more slits to form the one or more blocking structures.

According to another aspect of the present disclosure, a method for forming a three-dimensional (3D) memory device includes: forming a first multi-layer stacked structure over a substrate, wherein the first multi-layer stacked structure includes alternately stacked first layers and second layers, in which the second layers include a dielectric material; forming first capacitor structures penetrating the first multi-layer stacked structure and blocking structures penetrating the first multi-layer stacked structure, wherein each of the blocking structures separates subsets of the first capacitor structures from one another; forming a second multi-layer stacked structure over the first multi-layer stacked structure, wherein the second multi-layer stacked structure comprises a first insulating layer, a word line layer over the first insulating layer, and a second insulating layer over the word line layer; and forming contacts penetrating the second multi-layer stacked structure, wherein the contacts are disposed over the blocking structures, wherein the contacts are in contact with the word line layer of the second multi-layer stacked structure.

In some embodiments, the contacts penetrate through the second insulating layer of the second multi-layer stacked structure to the word line layer of the second multi-layer stacked structure.

In some embodiments, each of the first capacitor structures comprises a dielectric layer and an electrode layer, wherein the dielectric layer of a first capacitor structure is disposed between the electrode layer of the first capacitor structure and the first layers or the second layers of the first multi-layer stacked structure, and wherein the dielectric layer of each of the first capacitor structures comprises a ferroelectric material or an anti-ferroelectric material; and each of the blocking structures comprises a dielectric layer and a conductive layer, wherein the dielectric layer of each of the blocking structures comprises a ferroelectric material or an anti-ferroelectric material.

In some embodiments, each of the blocking structures further comprises a dielectric filling material.

In some embodiments, the method further includes: forming second holes penetrating the second multi-layer stacked structure, wherein the second holes are disposed over the first capacitor structures; and filling the second holes to form second capacitor structures, wherein each of the second capacitor structures comprises a dielectric layer and a conductive filling material.

In some embodiments, the method further includes: forming word line slits penetrating the second multi-layer stacked structure, wherein each of the word line slits penetrates through at least the second insulating layer of the second multi-layer stacked structure and the word line layer of the second multi-layer stacked structure, and wherein an extending direction of the word line slits is perpendicular to an extending direction of the blocking structures.

In some embodiments, the method further includes: forming bit lines over the second multi-layer stacked structure, wherein each of the bit lines is disposed over at least a respective one of the second capacitor structures.

In some embodiments, forming the first capacitor structures penetrating the first multi-layer stacked structure and the blocking structures penetrating the first multi-layer stacked structure comprises: forming, using a same mask, first holes penetrating the first multi-layer stacked structure and slits penetrating the first multi-layer stacked structure.

In some embodiments, forming the first capacitor structures penetrating the first multi-layer stacked structure and forming the blocking structures penetrating the first multi-layer stacked structure further comprises: simultaneously filling the first holes to form the first capacitor structures and filling the slits to form the blocking structures, respectively.

According to another aspect of the present disclosure, a 3D memory device includes a memory array, wherein the memory array includes: a first multi-layer stacked structure, wherein the first multi-layer stacked structure includes alternately stacked dielectric layers and conductive layers; first capacitor structures penetrating the first multi-layer stacked structure, wherein each of the first capacitor structures comprises a dielectric layer and an electrode layer, wherein the dielectric layer of a first capacitor structure is disposed between the electrode layer of the first capacitor structure and the dielectric layers or the conductive layers of the first multi-layer stacked structure; and a blocking structure penetrating the first multi-layer stacked structure, wherein the blocking structure separates one subset of the first capacitor structures from another subset of the first capacitor structures, and wherein the blocking structure comprises a dielectric layer and a conductive layer.

In some embodiments, the dielectric layers of the first capacitor structures and the dielectric layer of the blocking structure comprise a same dielectric material; and the electrode layers of the first capacitor structures and the conductive layer of the blocking structure comprise a same conductive material.

In some embodiments, the dielectric layer of each of the first capacitor structures comprises a ferroelectric material or an anti-ferroelectric material; and the dielectric layer of the blocking structure comprises a ferroelectric material or an anti-ferroelectric material.

In some embodiments, the blocking structure further comprises a dielectric filling material, and wherein the conductive layer of the blocking structure is disposed between the dielectric layer of the blocking structure and the dielectric filling material.

In some embodiments, the memory array further comprises: a second multi-layer stacked structure over the first multi-layer stacked structure, wherein the second multi-layer stacked structure comprises a first insulating layer, a word line layer over the first insulating layer, and a second insulating layer over the word line layer.

In some embodiments, the memory array further comprises: second capacitor structures penetrating the second multi-layer stacked structure, wherein the second capacitor structures are disposed over the first capacitor structures, and wherein each of the second capacitor structure comprises a dielectric layer and a conductive filling material; and bit lines over the second multi-layer stacked structure, wherein each of the bit lines is disposed over at least a respective one of the second capacitor structures.

In some embodiments, the memory array further comprises: word line blocking structures penetrating the second multi-layer stacked structure, wherein each of the word line blocking structures penetrates through at least the second insulating layer of the second multi-layer stacked structure and the word line layer of the second multi-layer stacked structure, and wherein an extending direction of the word line blocking structures is perpendicular to an extending direction of the blocking structure.

In some embodiments, the word line blocking structures and the second capacitor structures are arranged in a staggered manner such that the word line blocking structures form a wavy outline.

In some embodiments, the memory array further comprises: a contact penetrating the second multi-layer stacked structure, wherein the contact is disposed over the blocking structure, wherein the contact penetrates through the second insulating layer of the second multi-layer stacked structure to the word line layer of the second multi-layer stacked structure, and wherein the contact is in contact with the word line layer of the second multi-layer stacked structure.

In some embodiments, more than one contacts are disposed over a respective blocking structure.

In some embodiments, the memory array comprises a plurality of blocking structures, wherein a contact is disposed at a first subset of the blocking structures, and wherein no contact is disposed at a second subset of the blocking structures.

In some embodiments, the 3D memory device further includes a peripheral circuit bonded to the memory array.

According to another aspect of the present disclosure, a 3D memory device includes a memory array, wherein the memory array includes: a first multi-layer stacked structure, wherein the first multi-layer stacked structure includes alternately stacked dielectric layers and conductive layers; first capacitor structures penetrating the first multi-layer stacked structure; a blocking structure penetrating the first multi-layer stacked structure, wherein the blocking structure separates one subset of the first capacitor structures from another subset of the first capacitor structures; a second multi-layer stacked structure over the first multi-layer stacked structure, wherein the second multi-layer stacked structure comprises a first insulating layer, a word line layer over the first insulating layer, and a second insulating layer over the word line layer; and a contact penetrating the second multi-layer stacked structure, wherein the contact is disposed over the blocking structure, and wherein the contact is in contact with the word line layer of the second multi-layer stacked structure.

In some embodiments, each of the first capacitor structures comprises a dielectric layer and an electrode layer; the blocking structure comprises a dielectric layer and a conductive layer; the dielectric layers of the first capacitor structures and the dielectric layer of the blocking structure comprise a same dielectric material; and the electrode layers of the first capacitor structures and the conductive layer of the blocking structure comprise a same conductive material.

In some embodiments, the dielectric layer of each of the first capacitor structures comprises a ferroelectric material or an anti-ferroelectric material; and the dielectric layer of the blocking structure comprises a ferroelectric material or an anti-ferroelectric material.

In some embodiments, the blocking structure further comprises a dielectric filling material, and wherein the conductive layer of the blocking structure is disposed between the dielectric layer of the blocking structure and the dielectric filling material.

In some embodiments, the memory array further comprises: second capacitor structures penetrating the second multi-layer stacked structure, wherein the second capacitor structures are disposed over the first capacitor structures, and wherein each of the second capacitor structure comprises a dielectric layer and a conductive filling material; and bit lines over the second multi-layer stacked structure, wherein each of the bit lines is disposed over at least a respective one of the second capacitor structures.

In some embodiments, the memory array further comprises: word line blocking structures penetrating the second multi-layer stacked structure, wherein each of the word line blocking structures penetrates through at least the second insulating layer of the second multi-layer stacked structure and the word line layer of the second multi-layer stacked structure, and wherein an extending direction of the word line blocking structures is perpendicular to an extending direction of the blocking structure.

In some embodiments, the word line blocking structures and the second capacitor structures are arranged in a staggered manner such that the word line blocking structures form a wavy outline.

In some embodiments, the 3D memory device further includes a peripheral circuit bonded to the memory array.

In some embodiments, more than one contacts are disposed over a respective blocking structure.

In some embodiments, the memory array comprises a plurality of blocking structures, wherein a contact is disposed at a first subset of the blocking structures, and wherein no contact is disposed at a second subset of the blocking structures.

The foregoing description of the specific embodiments will so reveal the general nature of the present disclosure that others can, by applying knowledge within the ordinary skill of the art, readily modify and/or adapt for various applications such specific embodiments, without undue experimentation, and/or without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been defined herein for the convenience of the description. Alternate boundaries can be defined so long as the specified functions and relationships thereof are appropriately performed.

The Summary and Abstract sections may set forth one or more but not necessarily all example embodiments of the present disclosure as contemplated by the inventor(s), and thus, are not intended to limit the present disclosure and the appended claims in any way.

The breadth and scope of the present disclosure should not be limited by any of the above-described example embodiments. Accordingly, other implementations also are within the scope of the claims.

What is claimed is:

1. A three-dimensional (3D) memory device comprising a memory array, wherein the memory array comprises:
a first multi-layer stacked structure, wherein the first multi-layer stacked structure comprises alternately stacked dielectric layers and conductive layers;
first capacitor structures penetrating the first multi-layer stacked structure, wherein the first capacitor structures comprises a dielectric layer and an electrode layer, wherein the dielectric layer of a first capacitor structure is disposed between the electrode layer of the first capacitor structure and the dielectric layers or the conductive layers of the first multi-layer stacked structure; and
a blocking structure penetrating the first multi-layer stacked structure, wherein the blocking structure separates one subset of the first capacitor structures from another subset of the first capacitor structures, and wherein the blocking structure comprises a dielectric layer and a conductive layer.

2. The 3D memory device of claim 1, wherein:
the dielectric layers of the first capacitor structures and the dielectric layer of the blocking structure comprise a same dielectric material; and
the electrode layers of the first capacitor structures and the conductive layer of the blocking structure comprise a same conductive material.

3. The 3D memory device of claim 1, wherein:
the dielectric layer of each of the first capacitor structures comprises a ferroelectric material or an anti-ferroelectric material; and
the dielectric layer of the blocking structure comprises a ferroelectric material or an anti-ferroelectric material.

4. The 3D memory device of claim 1, wherein the blocking structure further comprises a dielectric filling material, and wherein the conductive layer of the blocking structure is disposed between the dielectric layer of the blocking structure and the dielectric filling material.

5. The 3D memory device of claim 1, wherein the memory array further comprises:
a second multi-layer stacked structure over the first multi-layer stacked structure, wherein the second multi-layer stacked structure comprises a first insulating layer, a word line layer over the first insulating layer, and a second insulating layer over the word line layer.

6. The 3D memory device of claim 5, wherein the memory array further comprises:
second capacitor structures penetrating the second multi-layer stacked structure, wherein the second capacitor structures are disposed over the first capacitor structures, and wherein each of the second capacitor structure comprises a dielectric layer and a conductive filling material; and
bit lines over the second multi-layer stacked structure, wherein the bit lines are disposed over the second capacitor structures.

7. The 3D memory device of claim 6, wherein the memory array further comprises:
word line blocking structures penetrating the second multi-layer stacked structure, wherein the word line blocking structures penetrate through at least the second insulating layer of the second multi-layer stacked structure and the word line layer of the second multi-layer stacked structure.

8. The 3D memory device of claim 7, wherein an extending direction of the word line blocking structures is perpendicular to an extending direction of the blocking structure, and an extending direction of the bit lines is perpendicular to the extending direction of the word line blocking structures.

9. The 3D memory device of claim 7, wherein the word line blocking structures and the second capacitor structures are arranged in a staggered manner such that the word line blocking structures form a wavy outline.

10. The 3D memory device of claim 5, wherein the memory array further comprises:
a contact penetrating the second multi-layer stacked structure, wherein the contact is disposed over the blocking structure, wherein the contact penetrates through the second insulating layer of the second multi-layer stacked structure to the word line layer of the second multi-layer stacked structure, and wherein the contact is in contact with the word line layer of the second multi-layer stacked structure.

11. The 3D memory device of claim 10, wherein more than one contacts are disposed over a respective blocking structure.

12. The 3D memory device of claim 10, wherein the memory array comprises a plurality of blocking structures, wherein a contact is disposed at a first subset of the blocking structures, and wherein no contact is disposed at a second subset of the blocking structures.

13. The 3D memory device of claim 1, further comprising a peripheral circuit bonded to the memory array.

14. A three-dimensional (3D) memory device comprising a memory array, wherein the memory array comprises:
a first multi-layer stacked structure, wherein the first multi-layer stacked structure comprises alternately stacked dielectric layers and conductive layers;
first capacitor structures penetrating the first multi-layer stacked structure;
a blocking structure penetrating the first multi-layer stacked structure, wherein the blocking structure separates one subset of the first capacitor structures from another subset of the first capacitor structures;
a second multi-layer stacked structure over the first multi-layer stacked structure, wherein the second multi-layer stacked structure comprises a first insulating layer, a word line layer over the first insulating layer, and a second insulating layer over the word line layer; and
a contact penetrating the second multi-layer stacked structure, wherein the contact is disposed over the blocking structure, and wherein the contact is in contact with the word line layer of the second multi-layer stacked structure.

15. The 3D memory device of claim 14, wherein:
each of the first capacitor structures comprises a dielectric layer and an electrode layer;
the blocking structure comprises a dielectric layer and a conductive layer;
the dielectric layers of the first capacitor structures and the dielectric layer of the blocking structure comprise a same dielectric material; and
the electrode layers of the first capacitor structures and the conductive layer of the blocking structure comprise a same conductive material.

16. The 3D memory device of claim 14, wherein:
the dielectric layer of each of the first capacitor structures comprises a ferroelectric material or an anti-ferroelectric material; and
the dielectric layer of the blocking structure comprises a ferroelectric material or an anti-ferroelectric material.

17. The 3D memory device of claim 14, wherein the blocking structure further comprises a dielectric filling material, and wherein the conductive layer of the blocking structure is disposed between the dielectric layer of the blocking structure and the dielectric filling material.

18. The 3D memory device of claim 14, wherein the memory array further comprises:
second capacitor structures penetrating the second multi-layer stacked structure, wherein the second capacitor structures are disposed over the first capacitor structures, and wherein each of the second capacitor structure comprises a dielectric layer and a conductive filling material; and
bit lines over the second multi-layer stacked structure, wherein the bit lines are disposed over the second capacitor structures.

19. The 3D memory device of claim 14, wherein the memory array further comprises:
word line blocking structures penetrating the second multi-layer stacked structure, wherein the word line blocking structures penetrate through at least the second insulating layer of the second multi-layer stacked structure and the word line layer of the second multi-layer stacked structure, and wherein an extending direction of the word line blocking structures is perpendicular to an extending direction of the blocking structure.

20. A memory system, comprising a 3D memory device and a peripheral circuit bonded to the 3D memory device, wherein the 3D memory device comprises:
a first multi-layer stacked structure, wherein the first multi-layer stacked structure comprises alternately stacked dielectric layers and conductive layers;
first capacitor structures penetrating the first multi-layer stacked structure, wherein the first capacitor structures comprises a dielectric layer and an electrode layer, wherein the dielectric layer of a first capacitor structure is disposed between the electrode layer of the first capacitor structure and the dielectric layers or the conductive layers of the first multi-layer stacked structure; and
a blocking structure penetrating the first multi-layer stacked structure, wherein the blocking structure separates one subset of the first capacitor structures from another subset of the first capacitor structures, and wherein the blocking structure comprises a dielectric layer and a conductive layer.
